(19) United States
(12) Patent Application Publication
(10) Pub. No.: US 2007/0002346 A1
(43) Pub. Date: Jan. 4, 2007

(54) Image processing apparatus, image forming apparatus and image processing method

(75) Inventor: Naomi Nakane, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignees: Kabushiki Kaisha Toshiba, Minato-ku (JP); Toshiba Tec Kabushiki Kaisha, Shinagawa-ku (JP)

(21) Appl. No.: 11/477,976

(22) Filed: Jun. 29, 2006

(30) Foreign Application Priority Data
Jun. 30, 2005 (JP) 2005-193031

(51) Int. Cl. G03F 3/08

(52) U.S. Cl. 358/1.9; 358/515; 358/518

(57) ABSTRACT

To adjust a color tone such as hue and chroma of a single color image of optional two colors (for each color component), and to provide a favorite 2-color copy image close to the user's demand, there is provided as an embodiment an image processing apparatus having a color conversion unit which converts input image data to a predetermined color space, and a color adjustment unit which adjusts an output color based on the result of determination by a color judgment unit to determine a position in the coordinates of a converting color space to be assigned to a noticed pixel converted by the color conversion unit, and an image processing method.

### CROSS-REFERENCE TO RELATED APPLICATIONS

This application is based upon and claims the benefit of priority from prior Japanese Patent Application No. 2005-193031, filed Jun. 30, 2005, the entire contents of which are incorporated herein by reference.

### BACKGROUND OF THE INVENTION

1. Field of the Invention

The present invention relates to an image processing apparatus which processes a color image read from a document in an image forming apparatus such as a digital color copier for forming a copy image of a color image, an image forming apparatus such as a digital color copier using the image processing apparatus, and an image processing method.

2. Description of the Related Art

Multi functional peripherals (MFP) capable of editing, image reversing, density reversing, and partial coloring in addition to copying of image, has been widely used in recent years.

MFP capable of outputting multicolor or full-color images as well as a single black color image, has been practically used.

MFP capable of outputting a color image can also output a 2-color copy consisting of black and optional one color, or selecting two colors except black.

Jpn. Pat. Appln. KOKAI Publication No. 8-289165 discloses a means for independently adjusting an output density of 2-color image when making a 2-color copy.

However, the adjusting means disclosed in the Jpn. Pat. Appln. KOKAI Publication No. 8-289165 adjusts an image density, and does not intend to adjust a delicate hue in a color space.

As for the color reproducibility, particularly color tone of red (vermilion) of a seal stamp included in a black image and ink blue (blue black) to distinguish a signature on a copied document, the user may insist a favorite color tone, and it is difficult to completely satisfy the user's demand.

### BRIEF SUMMARY OF THE INVENTION

It is an object of the invention to provide an image processing apparatus capable of adjusting the color tone (hue and chroma) of individual color in an image output consisting of two optional colors, an image forming apparatus including the image processing apparatus, and an image processing method.

According to an aspect of the invention, there is provided an image processing apparatus comprising:

a color conversion unit which converts input image data to a predetermined color space;

a color judgment unit which determines a position in the coordinates of a converting color space to be assigned to a noticed pixel converted by the color conversion unit; and

a color adjustment unit which adjusts the color of the output corresponding to the input image data, based on the result of the decision by the color judgment unit.

According to another aspect of the invention, there is provided an image forming apparatus comprising:

a color conversion unit which converts input image data to a predetermined color space;

a color judgment unit which determines a position in the coordinates of a converting color space to be assigned to a noticed pixel converted by the color conversion unit;

a color adjustment unit which adjusts the color of the output corresponding to the input image data, based on the result of the decision by the color judgment unit; and

a density adjustment unit which adjusts a density level of achromatic color.

According to still another aspect of the invention, there is provided an image processing method comprising:

specifying two object colors in input image data;

inputting an adjustment value to adjust the tone (hue and chroma) of the color of a noticed pixel; and

determining the completion of input/adjustment of a new adjustment value, based on the color of the printed printout.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic diagram explaining an example of an image forming apparatus according to an embodiment of the invention;

FIG. 2 is a block diagram explaining a flow of image signal and control signals of the image forming apparatus of FIG. 1;

FIG. 3 is a block diagram explaining an example of a flow of processing to realize the invention;

FIGS. 4A and 4B are views explaining a color space changed by the invention;

FIG. 5 is a view explaining an example of display in an input unit used to instruct changing of a color space shown in FIGS. 4A and 4B;

FIG. 6 is a graph explaining an example of γ characteristic of a single color image (for each color component) changed by the color adjustment of the invention; and

FIG. 7 is a graph explaining an example of γ characteristic of a single color image (for each color component) changed by the color adjustment of the invention.

### DETAILED DESCRIPTION OF THE INVENTION

Embodiments of the invention will be explained in detail hereinafter with reference to the accompanying drawings.

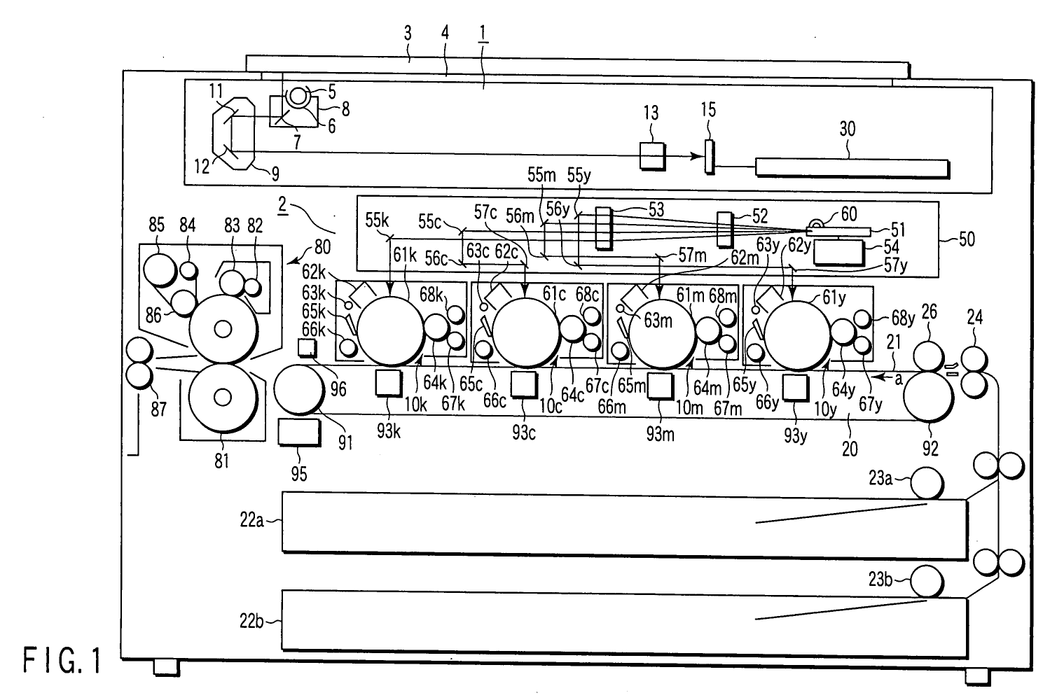

FIG. 1 shows a schematic diagram of an image forming apparatus according to an embodiment of the invention, represented by a digital color copier.

An image forming apparatus 1001 shown in FIG. 1 is largely divided into an image reading unit 1 (hereinafter called a color scanner) which reads a color image of document to be copied (duplicated/read), and an image forming unit 2 (hereinafter called a color printer) which forms a copy image of a read color image.

The color scanner 1 is has a document table 4 which is a transparent glass to set a document to read/copy, and a cover 4 which is provided at the top of the-document table and presses a document to the document table 4.

Under the document table 4, an exposure lamp 5 to illuminate a document set on the document table 4, a reflector 6 to condense the light from the exposure lamp 5 to the document, and a first mirror 7 to reflect the light reflected from the document to a predetermined direction to guide to an image reading sensor in a later stage, are provided integrally with a first carriage 8. The first carriage 8 is driven by a not-shown pulse motor through a not-shown toothed belt, and moved parallel along the underside of the document table 4.

In the direction to guide the light reflected from the first mirror 7 of the first carriage 8, a second carriage 9 which is provided parallel to the document table 4, and moved at a speed of ½ of the speed of moving the first carriage 8, is provided. The second carriage 9 has a second mirror 11 and a third mirror 12 provided at right angles to each other, which reflect the reflected light from the document guided by the first mirror 7 in a predetermined direction to guide to the image reading sensor.

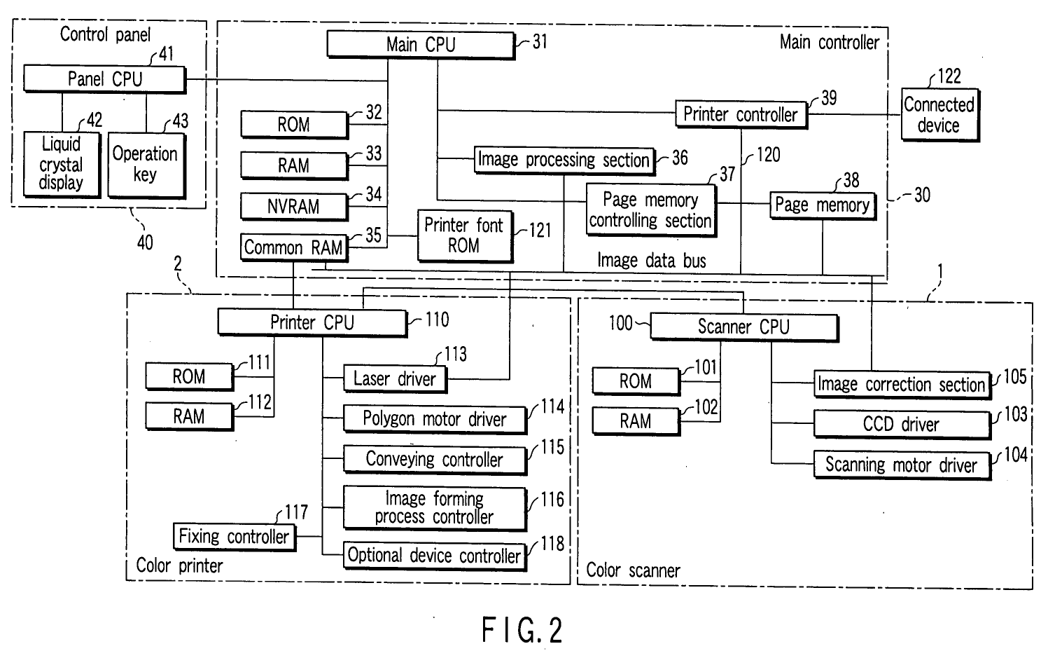

In the plane including the optical axis of the light reflected by the third mirror 12, an image forming lens 13 is provided to form an image at a predetermined magnification from the reflected light from the third mirror. In the plane orthogonal to the optical axis of the light passing through the image forming lens 13, color image sensor (an image reading sensor) 15 which converts the reflected light given convergence by the image forming lens 13 to an electric signal is provided. The color image sensor 15 is a 3-line CCD sensor composed of three CCD line sensors combined as one body, for example. The output from the 3-line CCD image sensor 15 is input to a control block 30 explained later with reference to FIG. 2.

In the image forming apparatus configured as described above, the light from the exposure lamp 5 of the color scanner 1 is condensed on the document set on the document table 4 by the reflector 6, and the light reflected from the document is applied to the 3-line CCD sensor 15 through the first mirror 7, second mirror 11, third mirror 12 and image forming lens 13. The reflected light from the document applied to the 3-line CCD sensor is separated to three prime colors of light known as R (Red), G (Green) and B (Blue), converted to respective electric signals, and supplied to an image processor (a control block) 30 explained later.

The color printer 2 has first to fourth image forming units 10y, 10m, 10c and 10k, which form color separated images for each color component, that is, four color images of Y (Yellow), M (Magenta, bright red), C (Cyan, deep purple) and K (Black) based on the known subtractive color mixing process. Hereinafter, a subscript (y, m, c, k) will be added to the same element provided in two or more quantities for each color component, and detailed explanation will be omitted.

Under the image forming unit 10(y, m, c, k), there is provided a conveying mechanism 20 including a conveying belt 21 in which images of color components formed by the image forming unit 10(y, m, c, k) are sequentially laid over.

The conveying belt 21 is held by a driving roller 91 rotated by a not-shown motor, and a driven roller 92 provided at a position of predetermined distance from the driving roller 91. The driven roller 92 gives a predetermined tension to the conveying belt 21 laid over the driving roller 91. When the driving roller 91 is rotated in a predetermined direction, an optional point of the conveying belt 21 (in the direction parallel to axial line of the driving roller 91 and driven roller 92) is moved in the direction of the arrow a from the driven roller 92 to the driving roller 91.

The first to fourth image forming units 10(y, m, c, k) are arranged in series along the conveying direction of an optional point of the conveying belt 21 from the driven roller 92 to the driving roller 91.

Each image forming unit 10(y, m, c, k) includes a photoconductive drum 6(y, m, c, k) having the outer circumference formed rotatably in the same direction, at the position contacting the conveying belt 21. Each photoconductive drum 61(y, m, c, k) is rotated at a predetermined speed by a not-shown motor.

The photoconductive drums 61(y, m, c, k) are arranged, so that the axial lines are spaced with equal intervals. The axial lines are arranged to be orthogonal to the image conveying direction by the conveying belt 21. In the explanation given hereinafter, the axial direction of each photoconductive drum 61(y, m, c, k) is a main scanning direction, and the rotating direction of each photoconductive drum 61(y, m, c, k), that is, the direction of moving an optional point of the conveying belt 21 (the direction of the arrow a) is a subsidiary scanning direction.

Around each photoconductive drum 61(y, m, c, k), a charger 62(y, m, c, k), a discharger 63(y, m, c, k), a developing roller 64(y, m, c, k), and a cleaning blade 65(y, m, c, k), which are given substantially the same length as the axial direction length of each photoconductive drum 61(y, m, c, k) and arranged parallel to the axial line of the photoconductive drum 61(y, m, c, k) along the main scanning direction, are provided sequentially along the rotating direction of each corresponding photoconductive drum 61(y, m, c, k). In the vicinity of the developing roller 64(y, m, c, k), a lower stirring roller 67(y, m, c, k), an upper stirring roller 68(y, m, c, k) and an exhaust toner collecting screw 66(y, m, c, k) are provided.

A transfer unit 93 for transferring a toner image formed on each photoconductive drum 61(y, m, c, k) to a transfer object or output paper sheet conveyed by the conveying belt 21, is provided corresponding to each photoconductive drum 61(y, m, c, k), at a position holding the conveying belt 21, or inside the conveying belt 21.

An image light or image information is radiated from an exposing unit 50 described later to the outer circumference of the photoconductive drum 61(y, m, c, k) between the charger 62(y, m, c, k) and developing roller 64(y, m, c, k).

Under the conveying mechanism 20, paper cassettes 22a and 22b containing output paper sheets P for holding an image formed by each image forming unit 10(y, m, c, k) are provided.

At one end of the paper cassettes 22a and 22b, or the side close to the driven roller 92, pickup rollers 23a and 23b are provided to take out one by one from the top of the paper sheets P contained in the paper cassettes 22a and 22b.

At the predetermined position between the pickup rollers 23a/23b and driven roller 92, a registration roller 24 is provided to adjust the front end of the output paper sheet P taken out of the cassettes 22a/22b to the front end of an image area of a Y-toner image formed by the photoconductive drum 61y in the image forming unit 10y.

The toner images formed on the other photoconductive drums 61(m, c, k) are adjusted in the image light output timing by the exposure unit 50, so that they are laid over at the transfer position where the transfer units 93(m, c, k) are opposed to the photoconductive drums 61(m, c, k), to meet the timing that the conveying belt 21 conveys the output paper sheet P.

Between the registration roller 24 and first image forming unit 10y, and at a predetermined position close to the driven roller 92, that is, substantially in the outer circumference of the driven roller 92 through the conveying belt 21, an absorbing roller 26 is provided to give a electrostatic absorbing force to the output paper sheet P delivered at a predetermined timing from the registration roller 24. The axial lines of the absorbing roller 26 and driven roller 92 are set parallel to each other.

At one end of the conveying belt 21, and in the vicinity of the driving roller 91, that is, substantially in the outer circumference of the driving roller 91 through the conveying belt 21, a position shift sensor 96 is provided to detect the position of the image formed on the conveying belt 21. The position shift sensor 96 is a translucent or reflective optical sensor.

In the outer circumference of the driving roller 91, and on the conveying belt 21 of the downstream side of the position shift sensor 96, a belt cleaning unit 95 is provided to eliminate the toner adhered to the conveying belt 21 or the dust of the output paper sheet P.

In the direction that the output paper sheet P conveyed through the conveying belt 21 is delivered from the driving roller 91 and conveyed furthermore, a fixing unit 80 is provided to fuse the toner image transferred to the output paper sheet P and fix the toner image or toner to the output paper sheet P.

The fixing unit 80 is given a predetermined nip when contacted to each other as a pair, and includes a pair of heating rollers 81 which fixes toner to a paper sheet by holding the paper sheet P having a transferred toner image in the nip, oil rollers 82 and 83 which are provided in the outer circumference of the heat rollers and apply a surface lubricant such as silicone oil, and a web pressing roller 86, a web winding roller 84 and a web roller 85 which are provided around the heating roller 81 contacting the toner and collect the toner adhered to the roller surface. The fixing unit fixes the toner formed on the paper sheet P, and exhausts the paper sheet through a pair of paper exhaust rollers 87.

The exposure unit 50 radiates the laser beam from a semiconductor laser element 60 emitted based on the image data (y, m, c, k) of color components generated by an image processor 36 described later with reference to FIG. 2, to the outer circumference of the photoconductive drums 61(y, m, c, k), and forms an electrostatic latent image on the photoconductive drums 61(y, m, c, k) to be given the toner of corresponding colors. In the optical path between the semiconductor laser element 60 and photoconductive drums 61(y, m, c, k), fθ lenses 52 and 53 are sequentially provided, which form an image by correcting the condensing size of a laser beam reflected through polygon mirrors 51 rotated by a polygon motor 54, for forming an electrostatic latent image by radiating a laser beam of each color image light to the corresponding photoconductive drums 61(y, m, c, k) in a predetermined condition.

Between the fθ lens 53 and photoconductive drums 61(y, m, c, k), folded mirrors 55(y, m, c, k), 56(m, c, k) and 57(m, c, k) are provided to guide the laser beam of each color component passing through the fθ lens 53 to the exposing position of each photoconductive drum 61(y, m, c, k). A laser beam for K (black) is guided to the photoconductive drum 61k without passing through the other mirrors, after folded by the mirror 55k.

FIG. 2 is a block diagram showing the electrical connection of the digital copier explained in FIG. 1, and a flow of control signals. In FIG. 2, a control system includes at least three CPUs, a main CPU (Central Processing Unit) 31 in a control block 30, a scanner CPU 100 in a color scanner 1, and a printer CPU 110 in a color printer 2.

The main CPU 31 is capable of transferring data and processing signals with the printer CPU 110, through a common RAM 35 accessible from the both. For example, when the main CPU 31 issues an operation instruction, the printer CPU 110 returns a status signal. The printer CPU 110 and scanner CPU 100 are serially connected, and when the printer CPU 110 issues an operation instruction, the scanner CPU 100 returns a status signal.

An operation panel 40 has a liquid crystal display 42 with a touch panel function, operation keys 43, and a panel CPU 41. The operation panel is connected to the main CPU 31.

The control block 30 includes a main CPU 31, a ROM 32, a RAM 33, a NVRAM 34, a common RAM 35, an image processor 36, a page memory controller 37, a page memory 38, a printer controller 39, and a printer font ROM 121, a shown in FIG. 2.

The main CPU 31 controls the operations of the control block 30, scanner 1 and printer 2. The ROM 32 previously stores a control program. The RAM 33 holds the temporarily generated data such as image data and the data input from the operation panel 40 for image forming, for a predetermined time. The NVRAM (Non Volatile TAM) 34 is a memory not losing data even if a power supply backed up by a battery (not shown) is interrupted, and holds data for a long period (over several years).

The RAM 35 is a RAM accessible from two ways, and used for data transfer between the main CPU 31 and printer CPU 110.

The page memory controller 37 stores image information read through the 3-line CCD sensor 15 in the page memory 38, or read and output the data to the image processor 36.

The page memory 38 has an area to store image information for several pages, and stores the data of compressed image information from the scanner 1 by units of page.

The printer font ROM 121 stores the font data corresponding to the print data.

The printer controller 39 develops the print data from an external device 122 such as a personal computer, to image data (final output image signal) with the resolution corresponding to the resolution given to that print data, according to the font data stored in the printer font ROM 121.

The color scanner 1 includes a scanner CPU 100, a ROM 101 storing a control program, a RAM 102 for storing data, a CCD driver 103 for driving the 3-line CCD sensor 15, a scanning motor driver 104 to control the rotation of a not-shown carriage motor for moving the first carriage 8, and an image correction unit 105.

The image correction unit 105 includes an A/D conversion circuit which converts an RGB analog signal output from the 3-line CCD sensor 15 to a digital signal, a shading correction circuit which corrects variations in the 3-line CCD sensor 15, or fluctuations in a threshold level with respect to an output signal from the color image sensor 15, and a line memory which once stores the shading corrected digital signal from the shading correction circuit.

The color printer 2 includes a printer CPU 110 to control the whole unit, a ROM 111 storing a control program, a RAM 112 for storing data, a laser driver 113 to drive the semiconductor laser oscillator 60, a polygon motor driver 114 to drive the polygon motor 54 of the exposure unit 50, a conveying controller 115 to control the conveying of paper sheet P by the conveying mechanism 20, a process controller 116 to control an image forming process known as charging, developing and transferring, by using the charger, developing unit and transfer unit, a fixing controller 117 to control the fixing unit 80, and an option controller 118 to control options.

The image processor 36, page memory 38, printer controller 39, image corrector 105 and laser driver 113 are connected through an image data bus 120.

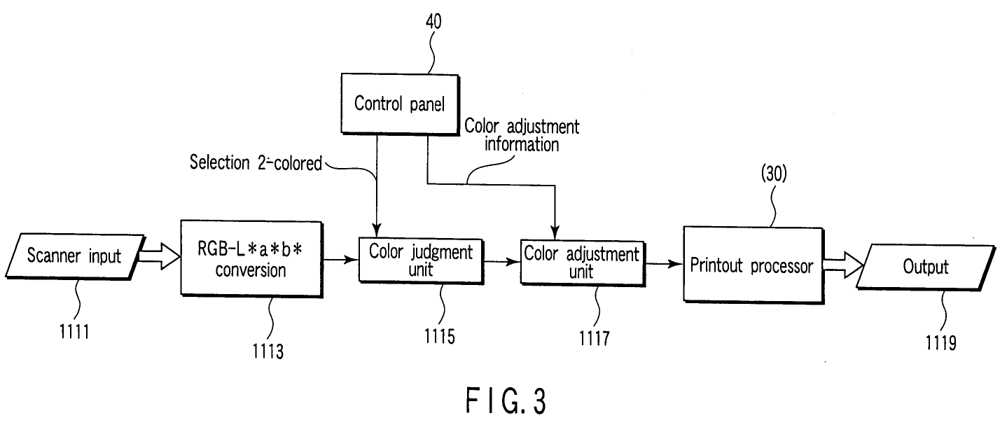

FIG. 3 shows an example of a flow of processing to realize the invention.

An explanation will be given on an example of adjusting the color tone of R (Red) in 2-color copying using two colors of red and blue.

a) A RGB-L*a*b* converter 1113A converts a RGB signal (i.e., a scanner input) 1111 input from the color scanner 1, to a “L*a*b*” signal indicated in the “L*a*b*” color space.

b) The user specifies (instructs to select) two colors from the liquid crystal panel (touch panel) 43 of the control panel 40 (refer to FIG. 2).

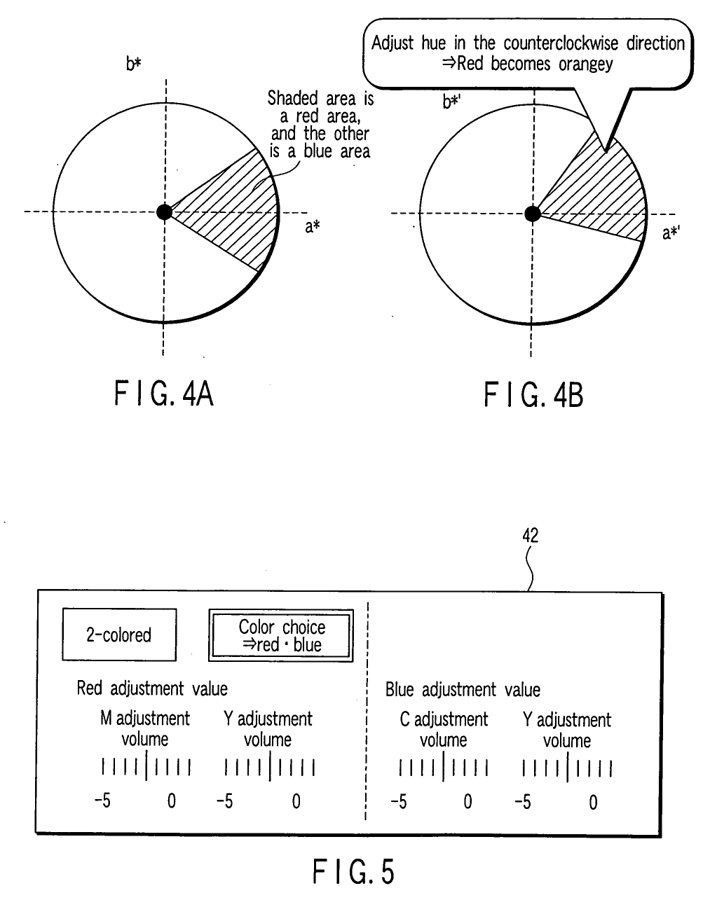

c) A color judging unit 1115 judges a noticed pixel based on “a*b*” of the “L*a*b*” that is the result of conversion in a). If the value of “a*b*” is within a predetermined space (a shaded area) in the coordinates of a color space explained hereinafter with reference to FIG. 4, the pixel (noticed) is judged red (R), and judged blue (B) if the value is out of the space.

d) Adjust the tone (hue and chroma) of the color of the noticed pixel through the liquid crystal panel (touch panel) 42 of the operation panel 40. R (Red) is an adjusting object in this example as shown by the example of FIG. 5, and the user instructs the adjusting values of Y (Yellow) and M (Magenta, bright red) to reproduce R, in a range of −5 to 5. If the adjusting object is B (Blue), adjust C (Cyan, deep purple) and Y (Yellow) to reproduce B.

e) For actual adjustment, change the values of LUT (Look Up Table) to be referred to by a color adjustment unit 1117. As LUT, a table having a certain relationship like “L*a*b*→L*′a*′b*′” is considerable. For example, a new (converted) table is obtained by converting the value of “a*b*” shown in FIG. 4A to “a*′b*′”. Changing the value of “a*b*” to the value of “a*′b*′” by shifting FIG. 4A to FIG. 4B, or turning counterclockwise in the “L*a*b*” color space means changing the hue of red (R) to “red including orangey red)”. Though not shown in the drawing, changing the value of “a*b*” shown in FIG. 4A to “a*″b*″” by shifting clockwise in the “L*a*b*” color space means changing the hue of red (R) to “bright red”.

f) The color adjusted by the adjustment unit 1117 is held, and the printer output processor outputs a print output 1119 to be able to obtain a copy image (printout). In the MFP shown in FIG. 1, the printer output processor supplies a final output image signal, so that the printer 2 (refer to FIG. 2) or an externally connected printer can output a copy image (printout). In the above-mentioned MFP, the image processor 36 (refer to FIG. 2) corresponds to the printer output processor. Of course, the printer output processor (image processor 36) adds gradation and contour correction to the output image signal adjusted in the tone.

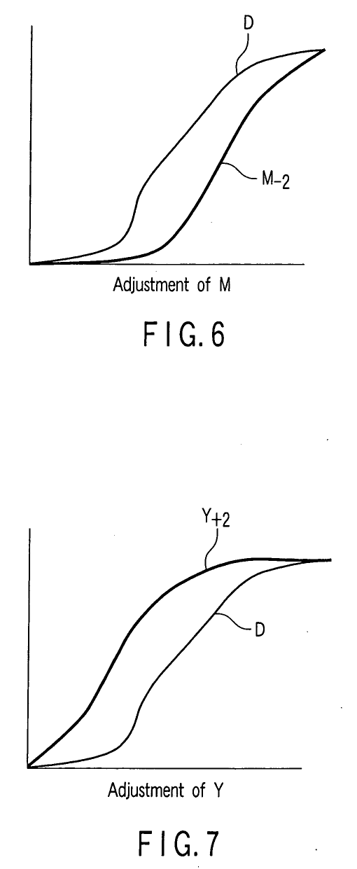

As a color adjusting method, the method of changing the “L*a*b*” color space shown in FIGS. 4A and 4B may be replaced by a method of directly changing the conversion characteristic of a single color image (for each color component) supplied from the image processor 36 to the printer 2 shown in FIG. 2, as shown in FIG. 6 and FIG. 7.

For example, Y and M are adjusted to change R (Red) as explained hereinbefore. As shown in FIG. 6, change the adjusted value of M from the default conversion characteristic D to M-2, for example. Further, as shown in FIG. 7, change the adjusted value of Y from the default conversion characteristic D to Y+2, for example.

As explained above, by applying the invention, the color of a single color image of optional two colors (for each color component) can be adjusted, and a favorite 2-color copy image close to the color tone demanded by the user can be obtained.

As to a black color image, adjustment of tone is unnecessary. Adjust the density by changing the curve of a density adjustment table, based on the value instructed from the operation panel (refer to the image processor 35 in FIG. 2).

The embodiment described above is one example of the proposal. The embodiment is not limited to the explained method. For example, the colors of 2-color copy are not limited to red (R) and blue (B). Other optional two colors may be selected. It is of course possible to combine chromatic color and achromatic color.

Further, a converter used for color judgment is not limited to RGB-L*a*b*. Other color spaces of x, y and z, for example, may be used.

When adjusting a tone color, a ratio of an optional single color image (for each color component) may be instructed from the operation panel. Density adjustment of an output image may be shared by the printer (printer output processor). In this case, taking Y and M as an example, patterns of the number expressed by the number of combinations of Y-M ratio x the number of density steps can be obtained.

As explained hereinbefore, according to the invention, for example, tone, hue and chroma of the color of a single color image of optional two colors (for each color component) can be adjusted, and a favorite 2-color copy image close to the color tone demanded by the user can be obtained.

The invention is not limited to the embodiments described hereinbefore. The invention may be embodied in other various forms without departing from its spirit or essential characteristics. Embodiments may be appropriately combined as far as possible. In this case, an effect by combination can be obtained.

What is claimed is:

1. An image processing apparatus comprising:
a color conversion unit which converts input image data to a predetermined color space;
a color judgment unit which determines a position in the coordinates of a converting color space to be assigned to a noticed pixel converted by the color conversion unit; and
a color adjustment unit which adjusts the color of the output corresponding to the input image data, based on the result of the decision by the color judgment unit.

2. The image processing apparatus according to claim 1, wherein the color conversion unit converts the input image data to a L*a*b* color space by using RGB-L*a*b* conversion.

3. An image forming apparatus comprising:
a color conversion unit which converts input image data to a predetermined color space;
a color judgment unit which determines a position in the coordinates of a converting color space to be assigned to a noticed pixel converted by the color conversion unit;
a color adjustment unit which adjusts the color of the output corresponding to the input image data, based on the result of the decision by the color judgment unit; and
a density adjustment unit which adjusts a density level of achromatic color.

4. The image forming apparatus according to claim 3, further comprising an output processor which adjusts the output of the adjustment unit to an output characteristic of an output image forming unit.

5. The image forming apparatus according to claim 3, wherein the color conversion unit converts the input image data to a L*a*b* color space by using RGB-L*a*b* conversion.

6. The image forming apparatus according to claim 5, further comprising an output processor which adjusts the output of the adjustment unit to an output characteristic of an output image forming unit.

7. An image processing method comprising:
specifying two object colors in input image data;
inputting an adjustment value to adjust the tone (hue and chroma) of the color of a noticed pixel; and
determining the completion of input/adjustment of a new adjustment value, based on the color of the printed printout.

8. The image processing method according to claim 7, wherein the input adjustment value includes one or both of “a*” and “b*”, in image data developing an image data input in RGB format to a L*a*b* color space.

9. The image processing method according to claim 7, wherein the input adjustment value includes the density of optional one of C, M and Y colors for forming a printout corresponding to the image data input in the RGB format.
